(19) United States
(12) Patent Application Publication
(10) Pub. No.: US 2019/0006425 A1
(43) Pub. Date: Jan. 3, 2019

(54) OLED LIGHTING COMBINED WITH OPV FOR WEARABLE AND SMART WINDOW APPLICATIONS

(71) Applicant: SABIC Global Technologies B.V., Bergen op Zoom (NL)

(72) Inventors: Sang Hoon KIM, Seoul (KR); Eun-Uk KIM, Gyeonggi-do (KR)

(21) Appl. No.: 16/064,108

(22) PCT Filed: Dec. 27, 2016
(86) PCT No.: PCT/IB2016/058025

§ 371 Date: Jun. 20, 2018

Related U.S. Application Data
(60) Provisional application No. 62/271,554, filed on Dec. 28, 2015.

(51) Int. Cl. H01L 27/28; H01L 27/30; H01L 51/52; H01L 27/32

(52) U.S. Cl. CPC H01L 27/288; H01L 27/304; F21Y 2115/15; H01L 27/3225; H01L 51/5287

(57) ABSTRACT

A lighting assembly that does not require an external power source is disclosed. The lighting assembly includes a substrate, an organic light-emitting device (OLED) having a bottom electrode disposed on the substrate, an organic light-emitting layer disposed on the bottom electrode and a top electrode on the organic light-emitting layer. The lighting assembly further includes an insulating layer disposed on the top electrode of the OLED and an organic photovoltaic (OPV) device disposed on the insulating layer. The OPV device includes a series of cells, each cell has a bottom electrode, an organic photovoltaic layer disposed on the bottom electrode, and a top electrode disposed on the organic photovoltaic layer, wherein each cell is connected to at least one adjacent cell. The OPV is electrically connected to the OLED and the OPV device is configured to produce electricity to directly power the OLED.

### TECHNICAL FIELD

The present disclosure relates to a lighting assembly that does not require a battery or an external power source and more particularly, to a lighting assembly that integrates an organic light-emitting device and an organic photovoltaic device.

### BACKGROUND

Today, organic light emitting devices/diodes (OLEDs) are increasingly used in lighting applications because they are more energy efficient than other conventional lighting sources. OLEDs typically have a stacked structure composed of one or more organic layers positioned between two electrodes, e.g. a cathode and an anode. The organic layers in an OLED are often composed of electroluminescent polymers that emit light when a voltage is applied across the anode and the cathode. At least one of the two electrodes, either the anode or the cathode electrode is formed from a transparent conductive material, which enables the light emitted from the OLED to be visible.

Generally, conventional lighting sources require an external power source or a battery for illumination. For example, FIG. 1(A) shows a home lighting appliance, i.e. a lamp, which has a power cable and needs external power socket. FIG. 1(B) shows a portable lighting appliance i.e., a flashlight, which requires a battery. OLED lighting applications, like conventional lighting sources, also require a power source to operate. Therefore, despite the fact that OLEDs offer certain advantages over other lighting sources such as having a thinner, more flexible and light-weight structure, the use of OLEDs has been somewhat restricted in portable lighting applications, such as clothing and smart windows.

Organic Photovoltaics (OPV) offer significant promise for the efficient and large scale conversion of light into electricity. In particular, OPV devices have proven to be a reliable and low-maintenance power source. Furthermore, OPV production consumes considerably less energy than the production of inorganic photovoltaic devices and OPV devices also require less material than inorganic crystalline photovoltaic devices. OPV cells, which are often referred to as solar cells, are semiconductor devices that are capable of converting light sources such as sunlight directly into electricity. OPV devices are composed of at least one solar cell, or an arrangement of solar cells. Organic solar cells are typically composed of at least one organic photovoltaic layer between two electrodes, e.g., a cathode and an anode.

One advantage of OPV devices is that they can be used as a direct power source. Additionally, most power sources require that the active components be periodically replaced or replenished, whereas the OPV device does not have this same need. For example, an OPV cell is able to generate and store electrical energy from ambient light and therefore is able to create a current to operate another device. Therefore, OPV devices may be advantageously combined with and used to directly power lighting applications, such as OLEDs.

There is a need, however, for the improved integration of OPV devices and OLEDs that more efficiently addresses power generation and consumption in these devices such that the integrated lighting assembly can be better utilized for applications such as clothing and smart windows. Accordingly, the disclosed OLED devices and processes are directed at overcoming one or more of these disadvantages in currently available OLEDs.

### SUMMARY

In accordance with one aspect of the disclosure, a lighting assembly that does not require an external power source is disclosed. The lighting assembly includes a substrate, an organic light-emitting device (OLED) having a bottom electrode disposed on the substrate, an organic light-emitting layer disposed on the bottom electrode and a top electrode on the organic light-emitting layer. The lighting assembly further includes an insulating layer disposed on the top electrode of the OLED and an organic photovoltaic (OPV) device disposed on the insulating layer. The OPV device includes a series of cells, each cell has a bottom electrode, an organic photovoltaic layer disposed on the bottom electrode, and a top electrode disposed on the organic photovoltaic layer, wherein each cell is connected to at least one adjacent cell. The OPV is electrically connected to the OLED and the OPV device is configured to produce electricity to directly power the OLED.

In accordance with another aspect of the disclosure, a lighting assembly is disclosed. The lighting assembly includes an organic light-emitting device (OLED) fiber that has a conductive core including a first electrode, an organic light-emitting layer surrounding the first electrode and a second electrode surrounding the organic light-emitting layer. The lighting assembly further includes an organic photovoltaic (OPV) fiber having a conductive core including a first electrode, an organic photovoltaic layer surrounding the first electrode, and a second electrode surrounding the organic photovoltaic layer. The OPV fiber is electrically connected to the OLED fiber and configured to directly power the OLED fiber.

In accordance with yet another aspect of the disclosure, a process for fabricating a lighting assembly, the process includes providing a substrate and providing an organic light-emitting device (OLED). The OLED includes a bottom electrode disposed on a substrate, an organic light-emitting layer disposed on the bottom electrode and a top electrode disposed on the organic light-emitting layer. The process further includes depositing an insulating layer on the top electrode of the OLED and providing an organic photovoltaic (OPV) device on the insulating layer. The OPV device includes a series of cells, each cell has a bottom electrode, an organic photovoltaic layer disposed on the bottom electrode, and a top electrode disposed on the organic photovoltaic layer, wherein each cell is connected to at least one adjacent cell. The process further includes connecting the OPV device to the OLED, wherein the OPV device is configured to directly power the OLED.

### BRIEF DESCRIPTION OF THE DRAWINGS

The above-mentioned and other features and advantages of this disclosure, and the manner of attaining them, will become apparent and be better understood by reference to the following description of one aspect of the disclosure in conjunction with the accompanying drawings, wherein:

FIG. 1(A) is a photograph of a conventional lighting application for a home lighting appliance requiring an external power source.

FIG. 1(B) is a photographic of a conventional lighting application for a portable lighting appliance requiring a battery.

FIGS. 2(A)-(F) are schematic perspective views of the process steps used to fabricate the lighting assembly according to one aspect of the present disclosure.

FIG. 3(A) is a schematic illustration of an OLED fiber and an OPV fiber according to one aspect of the present disclosure.

FIG. 3(B) is a schematic illustration of a transparent wire case according to one aspect of the present disclosure.

FIG. 3(C) is a schematic illustration of an OLED fiber and an OPV fiber according to one aspect of the present disclosure.

FIG. 4 is a schematic illustration of a lighting assembly having a transparent insulating layer according to one aspect of the present disclosure.

FIG. 5 is a schematic illustration of a lighting assembly having a reflective insulating layer according to one aspect of the present disclosure.

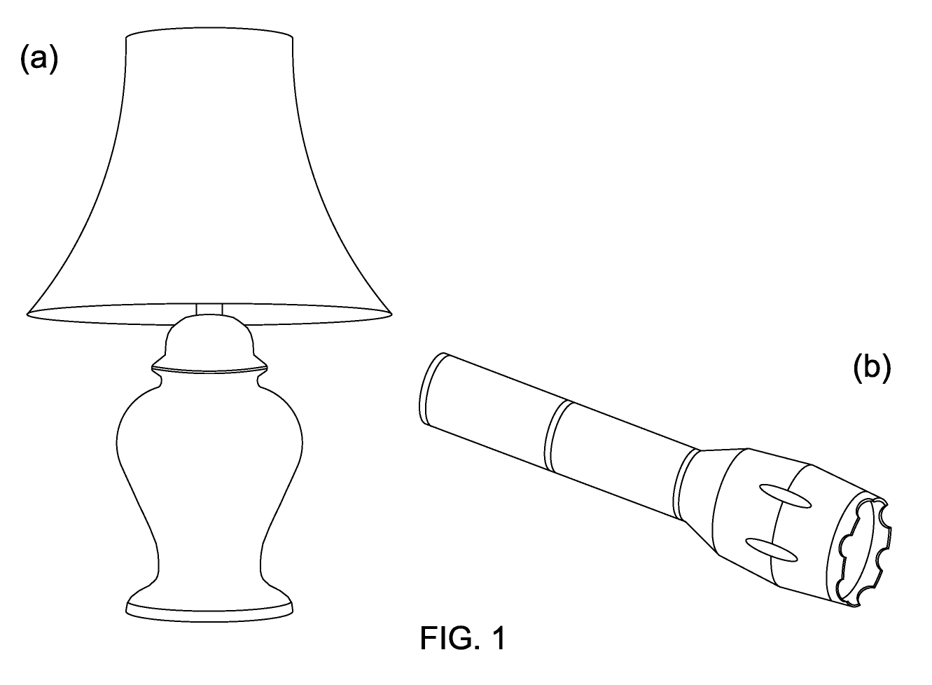

### DETAILED DESCRIPTION

### Lighting Assembly

The present disclosure provides a lighting assembly that is does not require a battery or an external power source. The lighting assembly integrates an organic light-emitting device (OLED) and an organic photovoltaic (OPV) device. The lighting assembly disclosed herein, therefore does not require the use of an external power source or a battery to operate. The OLED portion of the lighting assembly is able to generate light using the electricity directly produced by the OPV device. The power source for the OLED is the organic photovoltaic module. The OPV generates electrical energy from the ambient light and therefore is able to create a current for the OLED.

Therefore, the lighting assembly disclosed herein may be particularly useful for certain applications such as smart windows or wearable technology. For example, the lighting assembly may be integrated in clothing, or other wearable items, including but not limited to, gloves jewelry, bags, briefcases, purses, handbags, backpacks or wallets. Clothing items may include but is not limited to jackets, coats, belts, shoes, hats, and other clothing items and accessories. The lighting assembly disclosed herein may also be used as a portable lighting apparatus. In some aspects, the lighting assembly may be a window, a display, signage or the like. The term “smart window” may refer to an architectural, vehicle, or other window having a component that can darken and lighten according to a stimulus. In some aspects of the disclosure, the lighting assembly may encompass a substantial surface area. For example, the lighting assembly may have a width that is greater than 100 mm. In some aspects, the lighting assembly may have a width that is greater than 500 mm, greater than 200 mm, or greater than 150 mm.

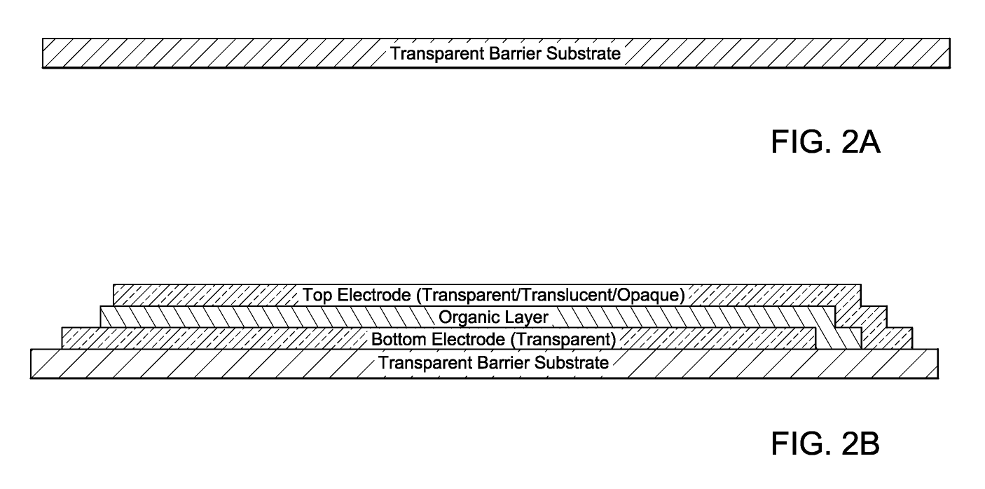

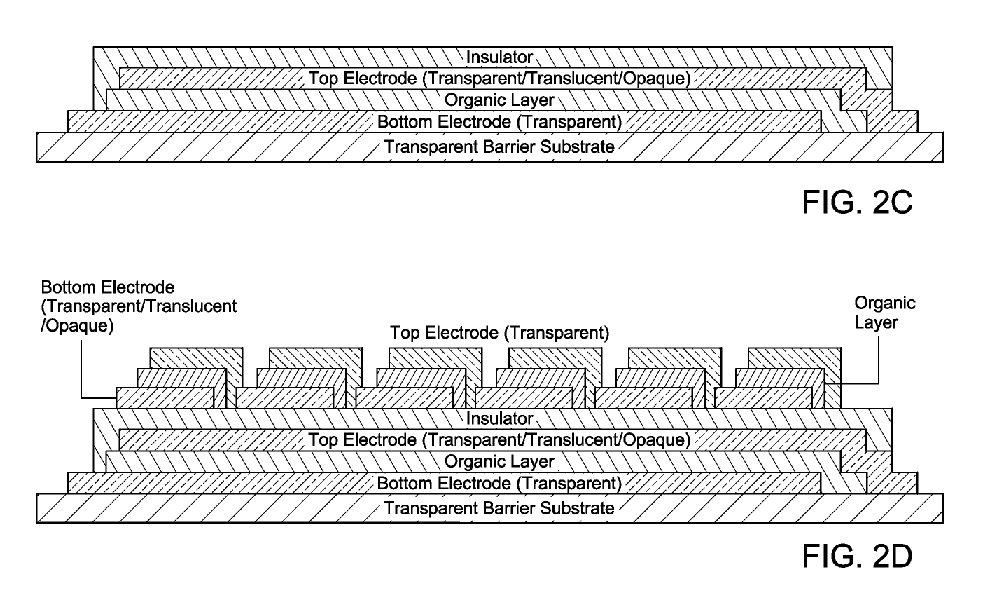

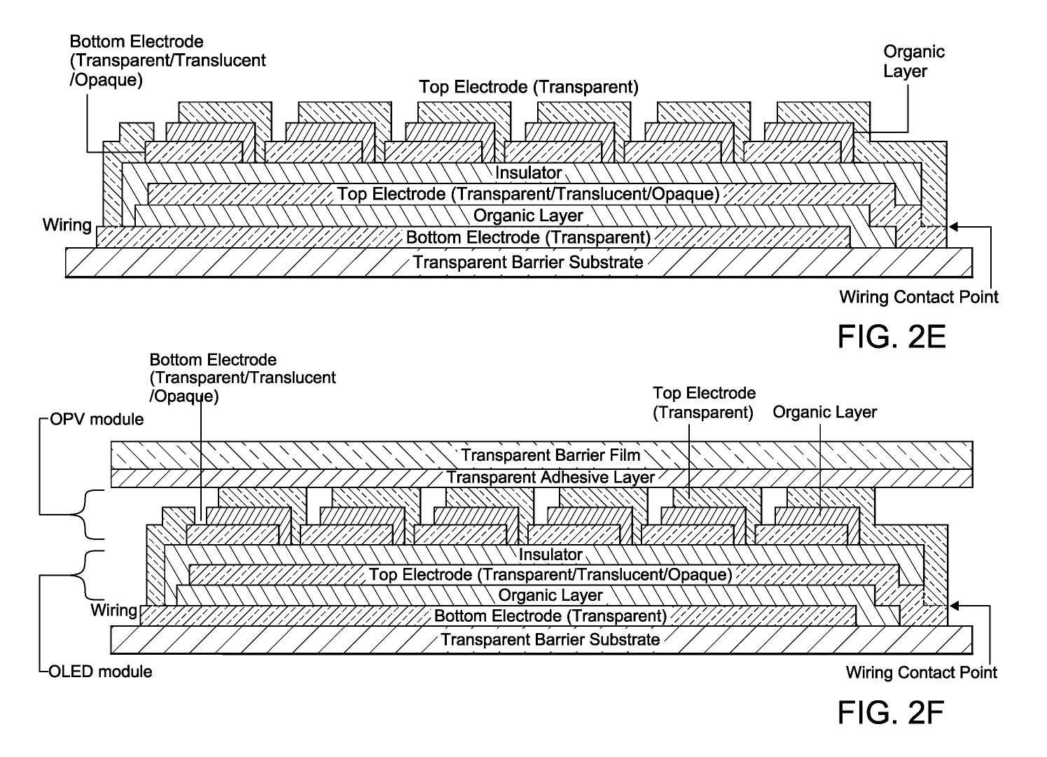

FIGS. 2(A)-2(F) illustrates a cross-sectional view of the fabrication of a lighting assembly according one aspect of the present disclosure. The basic configuration of the lighting assembly is a structure that includes an OLED device, an insulating layer and an OPV device. The insulating layer is arranged between the OLED device and the OPV device. The OLED device and the OPV device are electrically connected to each other. The lighting assembly may also include a transparent substrate. The OLED device may be mounted on the substrate. The lighting assembly may also include a transparent barrier film to encapsulate the lighting assembly. The transparent barrier film may be positioned over the OPV device opposite the insulating layer. An adhesive layer may be used to apply the transparent barrier film.

### Substrate

The lighting assembly disclosed herein includes a substrate. The substrate is generally configured to support both of the organic light emitting device as well as the organic photovoltaic device and the insulating layer. The substrate may also be configured to provide a barrier to the organic light emitting device and the organic photovoltaic device of the lighting assembly protecting them from exposure to water vapor, oxygen and/or other contaminants. In some aspects, the substrate may be transparent allowing light generated by the OLED to pass through the substrate while also allowing ambient light to pass through to the cells of the organic photovoltaic device. It is also contemplated that the substrate is non-transparent or opaque and semi-transparent. In some aspects, the substrate may be substantially flexible. In other aspects, the substrate may be rigid. In some aspects of the present disclosure, the substrate may be a single layer. The substrate, however, may also be composed of multiple layers. The substrate may be substantially planar as shown in FIG. 2(A) or non-planar. Providing the substrate is the first step in fabricating the lighting assembly of the present disclosure.

The substrate may comprise any suitable material known in the art. Suitable substrate materials may include, but are not limited to, glass, plastics, semiconductor materials such as silicon, and ceramics. Specific examples of the substrate may include, but are not limited to a plate or a foil of metal such as aluminum (including aluminum alloy), zinc, copper and iron; a film made of plastic such as cellulose acetate, polyethylene terephthalate (PET), polyethylene naphthalate (PEN), polyethylene, polyester, polyamide, polyimide, polystyrene, polypropylene, polycarbonate, polyvinyl acetal, aramid and polyphenylene sulfide; and paper having plastic (polyethylene, polypropylene, polystyrene, or the like) laminated thereon or paper coated with plastic (polyethylene, polypropylene, polystyrene, or the like), paper or a plastic film having the above-mentioned metal laminated thereon or vapor-deposited thereon.

The thickness of the substrate is not particularly limited. For lighting assemblies, particularly flexible lighting assemblies, the substrate thickness may be 300 μm or less, more preferably 200 μm or less, and even more preferably 100 μm or less. In some aspects of the disclosure, the substrate thickness may range from 10 μm to 50 μm.

### Organic Light-Emitting Device

As shown in FIG. 2(B), the OLED is provided on the substrate. The OLED includes a pair of electrodes that may function as an anode and a cathode with at least one organic light-emitting layer disposed between the anode and cathode. In one aspect, the top electrode shown in FIG. 2(B) may represent the cathode and bottom electrode may represent the anode. The anode or cathode or both may be a thin metal material. In some aspects, the anode and/or cathode material may be a transparent or substantially transparent conductive material. In one aspect, the anode and/or cathode material may be a transparent or substantially transparent metal. For example, the anode or cathode material may be indium-tin oxide (ITO), indium-zinc oxide (IZO) and tin oxide. However, for flexible lighting assemblies other metal oxides are preferred including, but not limited to, silver, aluminum- or indium-doped zinc oxide, magnesium-indium oxide, nickel-tungsten oxide and mixtures or alloys thereof. In addition to these oxides, metal nitrides, such as gallium nitride, and metal selenides, such as zinc selenide, and metal sulfides, such as zinc sulfide, can be used.

In some aspects, gold, iridium, molybdenum, palladium, and platinum may be useful as electrode materials if the electrode is not required to be transparent. These electrode layer materials may be deposited by any suitable means such as spray coating, evaporation, sputtering, chemical vapor deposition, or electrochemical means. In some aspects, application of the electrode layers may occur at room temperature and atmospheric pressure.

The OLED includes an organic light-emitting layer disposed between the pair of electrodes. The organic light-emitting layer may be a single layer or composed of multiple layers. In one aspect of the disclosure, the organic light-emitting layer may emit white light. The organic light-emitting layer may be formed by a vacuum evaporation method. The organic light-emitting layer may also be formed using a solution manufacturing process.

In some aspects, the OLED may emit light towards the substrate and the insulating layer. According to aspects of the present disclosure, the OLED may be a top emission type, a bottom emission type, or a double-sided emission type.

### Insulating Layer

Referring now to FIG. 2(C), the insulating layer is shown. The insulating layer is arranged between the OLED and the OPV device. The insulating layer may be selectively used to provide electrical separation between the OLED and the OPV device. For example, in FIG. 2(C), the insulating layer may be arranged to prevent direct electrical contact between the top electrode of the OLED and the bottom electrode of the OPV device. The OLED and OPV device are connected electrically to each other as described in detail below.

The insulating layer generally may be composed of any insulating material or any material with a resistance sufficiently high enough to prevent a current flow between the top and bottom electrodes via the insulating material. In some aspects, the insulating layer may be a transparent material or a reflective material. It may be preferred, however, that the insulating layer is reflective to enhance the optical efficiency of the both the OLED and the OPV device by gathering the transmitted light.

The insulating layer as shown in FIGS. 2(C)-2(F) is a layer deposited on the top electrode of the OLED enclosing the lateral edges of the top electrode and the organic light emitting layer in order to prevent a direct electrical contact between the top and bottom electrodes of the OLED. The insulating layer may also cover at least the area of the top electrode of the OLED covered by the bottom electrode of the OPV device to prevent any direct electrical contact between these layers.

To provide electrical contacts to the top electrode in order to connect the top electrode of the OLED to the OPV device, the intended contact areas (contact pad) of the top electrode may be not covered by the insulating layer. As shown in FIGS. 2(C)-2(F), the organic light emitting layer is shaped to prevent the top electrode from contacting the bottom electrode. The organic light emitting layer may cover an area of the bottom electrode larger than the area which is covered by the top electrode.

### Organic Photovoltaic Device

As shown in FIG. 2(D), the OPV device is provided on the insulating layer opposite from the OLED. The OPV device includes one or more OPV cells that are arranged on the insulating layer. The OPV cells in FIG. 2(D) do not completely cover the insulating layer. As shown in FIG. 2(D), the OPV cells may be substantially aligned in a horizontal and vertical orientation on the insulating layer and thus together may define openings through the insulating layer of the lighting assembly.

Each OPV cell may be electrically connected to the adjacent OPV cell(s) in the OPV device. For example, in one aspect of the disclosure the OPV device may include a first OPV cell and a second OPV cell. The first and the second OPV cells may be adjacent to each other and connected in series such that the current may flow through the organic photovoltaic layer of the first OPV cell to the organic photovoltaic layer of the second OPV cell. In some aspects of the disclosure, the bottom electrode of a cell is connected to the top electrode of an adjacent cell.

The construction of the OPV cell may be similar to the construction of the OLED. Each OPV cell includes a pair of electrodes that may function as an anode and a cathode with at least one organic photovoltaic layer disposed between the anode and cathode. In one aspect, the top electrode shown in FIG. 2(B) may represent the cathode and the bottom electrode may represent the anode. The anode or cathode or both may be a thin metal material. In some aspects, the anode and/or cathode material may be a transparent or substantially transparent conductive material. In one aspect, the anode and/or cathode material may be a transparent or substantially transparent metal. For example, the anode or cathode material may be indium-tin oxide (ITO), indium-zinc oxide (IZO) and tin oxide. However, for flexible lighting assemblies other metal oxides are preferred including, but not limited to, silver, aluminum- or indium-doped zinc oxide, magnesium-indium oxide, nickel-tungsten oxide and mixtures or alloys thereof. In addition to these oxides, metal nitrides, such as gallium nitride, and metal selenides, such as zinc selenide, and metal sulfides, such as zinc sulfide, can be used.

In some aspects, gold, iridium, molybdenum, palladium, and platinum may be useful as electrode materials if the electrode is not required to be transparent. These electrode layer materials may be deposited by any suitable means such as spray coating, evaporation, sputtering, chemical vapor deposition, or electrochemical means. In some aspects, application of the electrode layers may occur at room temperature and atmospheric pressure.

### Organic Photoactive Layer

The organic photovoltaic layer may be formed by thermal evaporation, spin coating, screen printing, inkjet printing, spray printing, slot die coating, bar coating and the like. The organic photovoltaic layer may be transparent. In some aspects of the disclosure, both of the OPV device and the OLED may be transparent. The organic photovoltaic layer may include one or more layers as needed.

In some aspects of the disclosure, the thickness of the organic photovoltaic layer may range from about 5 nm to about 2000 nm. In some aspects, the thickness of the organic photovoltaic layer may range from about 50 nm to about 1000 nm. In some aspects, the thickness of the organic photovoltaic layer may range from about 100 nm to about 300 nm.

The organic photovoltaic layer is comprised of organic photoactive materials that in response to the absorption of light are able to convert the light energy to electrical energy. Suitable organic photoactive materials used to form the organic photovoltaic layer are well known in the art and may include polymers such as PEDOT:PSS. The organic photovoltaic layer may further include optional layers such as electron transport layers between the organic photovoltaic layer and the electrode layers and/or hole transport layers between the other electrode layers.

In some aspects of the disclosure, the lighting assembly may be in the form of an elongated fiber. A lighting assembly having an elongated fiber structure may be particularly useful for clothing or other various wearable applications. For example, the fiber may be woven into fabric.

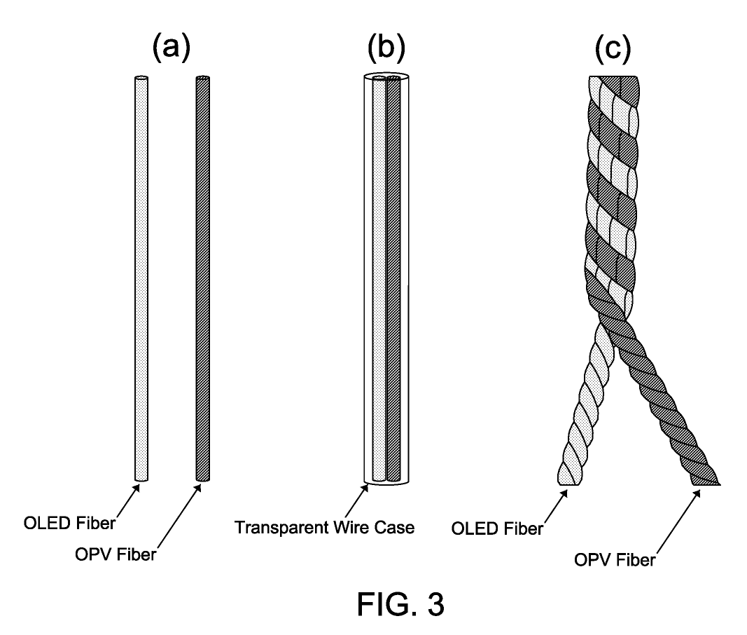

For a lighting assembly that is in the form of a fiber, both of the OLED and the OPV device may be elongated fibers as shown in FIG. 3(A). For an OLED fiber, the fiber may have a conductive core, including a first electrode. An organic light emitting layer may surround the conductive core. A transparent second electrode may surround the organic light emitting layer. For an OPV fiber, the fiber may also have a conductive core, including a first electrode. An organic photovoltaic layer may surround the conductive core. A transparent second electrode may surround the organic photovoltaic layer.

In one aspect of the disclosure, integration of the OLED fiber and the OPV fiber to form a lighting assembly may be accomplished by using a transparent wire case. As shown in FIG. 3(B), the OLED fiber and the OPV fiber may be placed inside the transparent wire case to form a fiber lighting assembly. In some aspects, there may be more than one OLED fiber and/or OPV fibers. The transparent wire case may be similar to the transparent barrier film previously described for the planar-stacked lighting applications. In this regard, the wire case may encapsulate the lighting application protecting the OLED fibers and the OPV fibers contained therein from moisture and oxygen. In one aspect, the transparent wire case may be flexible.

In another aspect of the disclosure, the OLED fiber and the OPV fiber may be twisted or braided together to form a rope-like structure. A lighting assembly having the rope-like structure is shown in FIG. 3(C). Multiple OLED fibers and multiple OPV fibers may be twisted or braided together to form the rope-like structure. Many different braided patterns may also be used to form the rope-like structure of the lighting assembly.

For lighting assemblies described herein that have either a wire structure or a rope-like structure using OLED fibers and OPV fibers, an insulating layer may not be required to electrically separate the OLED fibers from the OPV fibers. An insulating layer, however, may be required in the stacked planar lighting assembly as shown in FIG. 2. Portions of the outer layers (second electrodes) of the OLED fiber and OPV device are in contact with each other in both the wire structure and in the rope-like structure as needed. The conductive core (first electrode) of the OPV fiber and the conductive core (first electrode) of the OLED fiber may be electrically connected to each other. The structures of the lighting assemblies that are in the form of a transparent wire and rope are similar to the planar-stacked lighting assemblies, except for the need for an insulating layer in the planar-stacked lighting assemblies.

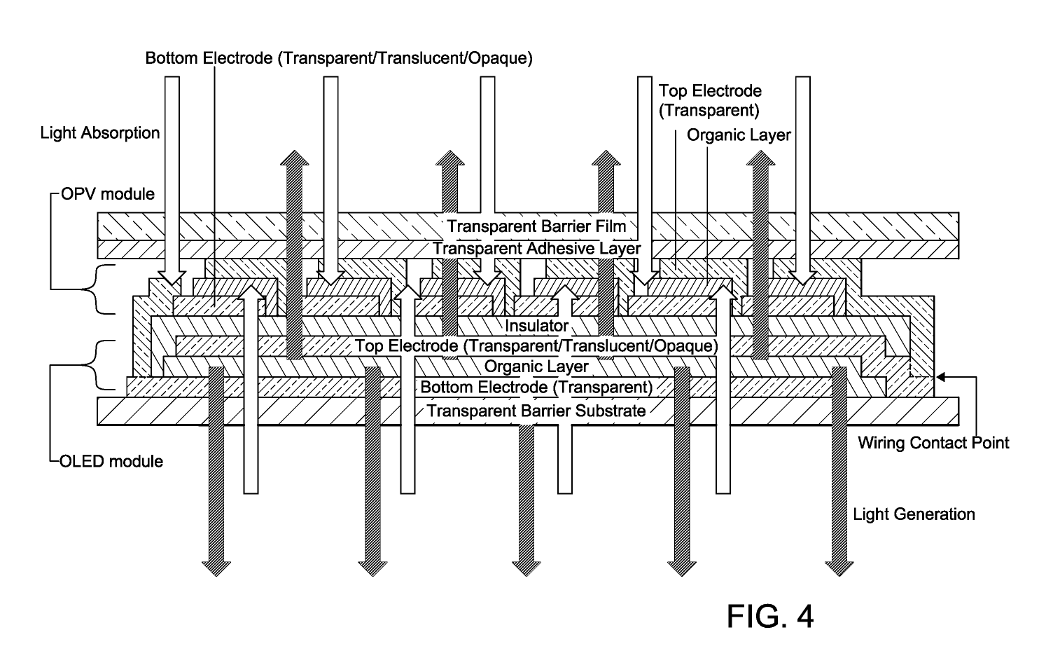

Referring now to FIG. 4, a lighting assembly according to one aspect of the disclosure is illustrated. The lighting assembly in FIG. 4 includes an insulating layer that is transparent. Because the insulating layer is transparent, it is possible to see through all sides of the lighting assembly. The lighting assembly may, for example, be entirely transparent and may have front and rear visibility in some aspects. In this aspect, the lighting assembly may be a transparent screen that has functionality on opposing surfaces.

The lighting assembly shown in FIG. 4 may be useful for certain applications such as smart windows and/or displays. The OPV device may absorb the light from both sides because this integrated device has a transparent insulating layer. The OLED may also emit the light to both sides of the lighting assembly for the same reason. At first, the light illuminates to the series of cells in the OPV device. In this aspect, the OPV may use the light generated by the OLED to produce power. The series of cells in the OPV device absorbs the light and generates electrical power. This electrical power can be used from each terminal electrode of the OPV device. The OPV device has terminal OPV cells that have terminal electrodes. These terminal electrodes may be used to connect the OPV device to the OLED. For example, to integrate the OPV device and OLED, each terminal of the OPV and OLED is wired to use the power generated. The power generated by the OPV device is delivered directly to the OLED through each terminal electrode. The OLED receives electrical power from the OPV device, and then uses the power to generate a current across the top and bottom electrodes of the OLED to generate light. In this aspect, the organic light-emitting layer determines the wavelength range of absorbency and the wavelength range of emission. Depending on the type and/or configuration of the organic light-emitting layer, the lighting assembly may generate a wide spectrum of color, and even white light.

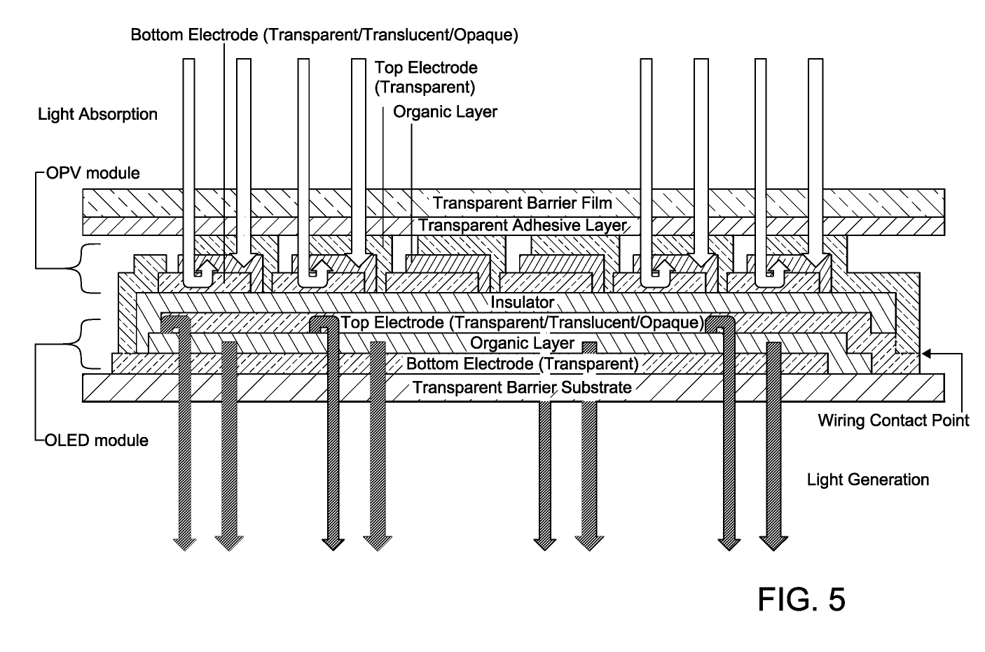

Referring now to FIG. 5, a lighting assembly according to another aspect of the disclosure is illustrated. The lighting assembly in FIG. 4 includes an insulating layer that is reflective or mirrored. In this case, the lighting assembly may be used for an outer wall or an application that does not require complete transparency or that the user is able to see through the lighting assembly. Because the insulating layer is reflective, the lighting assembly shown in FIG. 5 may display colors more clearly. This advantage may be particularly useful for certain applications such as smart windows, displays or signage where more intense color may be required to attract attention to the lighting assembly. The reflective insulating layers prevent the light from entering the OPV device side of the lighting assembly and the light from OLED is not diluted from any external light. Therefore, more clear light is visible than in the case of an insulating layer.

It will be appreciated that the foregoing description provides examples of the disclosed system and technique. However, it is contemplated that other implementations of the disclosure may differ in detail from the foregoing examples. All references to the disclosure or examples thereof are intended to reference the particular example being discussed at that point and are not intended to imply any limitation as to the scope of the disclosure more generally. All language of distinction and disparagement with respect to certain features is intended to indicate a lack of preference for those features, but not to exclude such from the scope of the disclosure entirely unless otherwise indicated.

### Definitions

It is to be understood that the terminology used herein is for the purpose of describing particular aspects only and is not intended to be limiting. As used in the specification and in the claims, the term “comprising” can include the embodiments “consisting of” and “consisting essentially of.” Unless defined otherwise, all technical and scientific terms used herein have the same meaning as commonly understood by one of ordinary skill in the art to which this disclosure belongs. In this specification and in the claims which follow, reference will be made to a number of terms which shall be defined herein.

As used in the specification and the appended claims, the singular forms “a,” “an” and “the” include plural equivalents unless the context clearly dictates otherwise. Thus, for example, reference to “a polycarbonate polymer” includes mixtures of two or more polycarbonate polymers.

As used herein, the term “combination” is inclusive of blends, mixtures, alloys, reaction products, and the like.

Ranges can be expressed herein as from one particular value to another particular value. When such a range is expressed, another aspect includes from the one particular value and/or to the other particular value. Similarly, when values are expressed as approximations, by use of the antecedent ‘about,’ it will be understood that the particular value forms another aspect. It will be further understood that the endpoints of each of the ranges are significant both in relation to the other endpoint, and independently of the other endpoint. It is also understood that there are a number of values disclosed herein, and that each value is also herein disclosed as “about” that particular value in addition to the value itself. For example, if the value “10” is disclosed, then “about 10” is also disclosed. It is also understood that each unit between two particular units are also disclosed. For example, if 10 and 15 are disclosed, then 11, 12, 13, and 14 are also disclosed.

As used herein, the terms “about” and “at or about” mean that the amount or value in question can be the value designated some other value approximately or about the same. It is generally understood, as used herein, that it is the nominal value indicated ±5% variation unless otherwise indicated or inferred. The term is intended to convey that similar values promote equivalent results or effects recited in the claims. That is, it is understood that amounts, sizes, formulations, parameters, and other quantities and characteristics are not and need not be exact, but can be approximate and/or larger or smaller, as desired, reflecting tolerances, conversion factors, rounding off, measurement error and the like, and other factors known to those of skill in the art. In general, an amount, size, formulation, parameter or other quantity or characteristic is “about” or “approximate” whether or not expressly stated to be such. It is understood that where “about” is used before a quantitative value, the parameter also includes the specific quantitative value itself, unless specifically stated otherwise.

Disclosed are the components to be used to prepare the compositions of the disclosure as well as the compositions themselves to be used within the methods disclosed herein. These and other materials are disclosed herein, and it is understood that when combinations, subsets, interactions, groups, etc. of these materials are disclosed that while specific reference of each various individual and collective combinations and permutation of these compounds cannot be explicitly disclosed, each is specifically contemplated and described herein. For example, if a particular compound is disclosed and discussed and a number of modifications that can be made to a number of molecules including the compounds are discussed, specifically contemplated is each and every combination and permutation of the compound and the modifications that are possible unless specifically indicated to the contrary. Thus, if a class of molecules A, B, and C are disclosed as well as a class of molecules D, E, and F and an example of a combination molecule, A-D is disclosed, then even if each is not individually recited each is individually and collectively contemplated meaning combinations, A-E, A-F, B-D, B-E, B-F, C-D, C-E, and C-F are considered disclosed. Likewise, any subset or combination of these is also disclosed. Thus, for example, the sub-group of A-E, B-F, and C-E would be considered disclosed. This concept applies to all aspects of this application including, but not limited to, steps in methods of making and using the compositions of the disclosure. Thus, if there are a variety of additional steps that can be performed it is understood that each of these additional steps can be performed with any specific aspect or combination of aspects of the methods of the disclosure.

As used herein, the term “light” means electromagnetic radiation including ultraviolet, visible or infrared radiation.

As used herein, the term “transparent” means that the level of transmittance for a disclosed composition is greater than 50%. In some embodiments, the transmittance can be at least 60%, 70%, 80%, 85%, 90%, or 95%, or any range of transmittance values derived from the above exemplified values. In the definition of “transparent”, the term “transmittance” refers to the amount of incident light that passes through a sample measured in accordance with ASTM D1003 at a thickness of 3.2 millimeters.

As used herein, the term “layer” As used herein, a “layer” of a given material includes a region of that material the thickness of which is smaller than either of its length or width. Examples of layers may include sheets, foils, films, laminations, coatings, blends of organic polymers, metal plating, and adhesion layer(s), for example. Further, a “layer” as used herein need not be planar, but may alternatively be folded, bent or otherwise contoured in at least one direction, for example.

Unless otherwise stated to the contrary herein, all test standards are the most recent standard in effect at the time of filing this application.

Aspects

The present disclosure comprises at least the following aspects.

Aspect 1. A lighting assembly comprising: (a) a substrate; (b) an organic light-emitting device (OLED) including a bottom electrode disposed on the substrate, an organic light-emitting layer disposed on the bottom electrode and a top electrode disposed on the organic light-emitting layer; (c) an insulating layer disposed on the top electrode of the OLED; and (d) an organic photovoltaic (OPV) device disposed on the insulating layer, the OPV device including a series of cells, each cell comprising a bottom electrode, an organic photovoltaic layer disposed on the bottom electrode, and a top electrode disposed on the organic photovoltaic layer, wherein each cell is connected to at least one adjacent cell, and wherein the OPV device is electrically connected to the OLED and configured to directly power the OLED.

Aspect 2. The lighting assembly of aspect 1, wherein the assembly requires no external power source.

Aspect 3. The lighting assembly of aspect 1, further comprising a battery to selectively supplement power to the OLED as needed.

Aspect 4. The lighting assembly of any one of the preceding aspects, wherein the top and bottom electrodes of the OPV device and the organic photovoltaic layer are disposed on the insulating layer.

Aspect 5. The lighting assembly of any one of the preceding aspects, wherein the bottom electrode of each cell is electrically connected to the top electrode of an adjacent cell.

Aspect 6. The lighting assembly of any one of the preceding aspects, wherein the series of cells of the OPV device are aligned in a horizontal and vertical orientation on the insulating layer defining a plurality of openings through the lighting assembly.

Aspect 7. The lighting assembly of any one of the preceding aspects, wherein each electrode of the OPV device and OLED are coupled together as one.

Aspect 8. The lighting assembly of any one of the preceding aspects, wherein the top electrode of the OLED is electrically connected to at least one of the top electrodes of the cells in the OPV device.

Aspect 9. The lighting assembly of any one of the preceding aspects, wherein the bottom electrode of the OLED is electrically connected to at least one bottom electrode of the cells in the OPV device.

Aspect 10. The lighting assembly of any one of the preceding aspects, wherein the top and bottom electrodes in the OLED and each cell in the OPV device comprise a cathode and an anode, and the cathode of the OLED is electrically connected at least one cathode of the OPV device and the anode of the OLED is electrically connected to at least one anode the OPV device.

Aspect 11. The lighting assembly of any one of the preceding aspects, further comprising a transparent barrier film disposed on the OPV device opposite the insulating layer.

Aspect 12. The lighting assembly of any one of the preceding aspects, further comprising an adhesive layer disposed between the transparent barrier film and the OPV device, wherein the adhesive layer is transparent.

Aspect 13. The lighting assembly of any one of the preceding aspects, wherein at least one of the top and bottom electrodes and the organic light-emitting layer of the OLED is formed using a vacuum process or a solution process.

Aspect 14. The lighting assembly of any one of the preceding aspects, wherein at least one of the top and bottom electrodes and the organic photovoltaic layer of the OPV device is formed using a vacuum process or a solution process.

Aspect 15. The lighting assembly of any one of the preceding aspects, wherein at least one layer of the OLED is deposited using a vacuum process or a solution process.

Aspect 16. The lighting assembly of any one of the preceding aspects, wherein at least one layer of the OPV device is deposited using a vacuum process or a solution process.

Aspect 17. The lighting assembly of any one of the preceding aspects, wherein each layer of the assembly is deposited using a vacuum process or a solution process.

Aspect 18. The lighting assembly of any one of the preceding aspects, wherein the insulating layer is transparent or reflective.

Aspect 19. The lighting assembly of any one of the preceding aspects, wherein the substrate is flexible.

Aspect 20. The lighting assembly of any one of the preceding aspects, wherein the substrate is transparent.

Aspect 21. The lighting assembly of any one of the preceding aspects, wherein the top and bottom electrodes in the OLED and the series of cells are transparent or translucent.

Aspect 22. The lighting assembly of any one of the preceding aspects, wherein the top and bottom electrodes in the OLED are transparent or translucent.

Aspect 23. The lighting assembly of any one of the preceding aspects, wherein the top and bottom electrodes in the series of cells in the OPV device are transparent or translucent.

Aspect 24. The lighting assembly of any one of the preceding aspects, wherein the organic light-emitting layer is disposed on the top surface and the lateral surfaces of the bottom electrode.

Aspect 25. The lighting assembly of any one of the preceding aspects, wherein the organic light-emitting layer is a single continuous layer disposed on the top surface of the substrate and the top surface of the bottom electrode of the OLED.

Aspect 26. The lighting assembly of any one of the preceding aspects, wherein the top electrode of the OLED is disposed on the top surface of the organic light-emitting layer and the top surface of the substrate.

Aspect 27. The lighting assembly of any one of the preceding aspects, wherein the insulating layer is disposed on the top surface of the top electrode of the OLED, at least a portion of the top surface of the bottom electrode of the OLED, and at least one surface of the top and bottom electrodes and the organic photovoltaic layer of the OPV devices.

Aspect 28. The lighting assembly of any one of the preceding aspects, wherein the assembly is a smart window or display.

Aspect 29. The lighting assembly of any one of the preceding aspects, wherein the assembly is transparent.

Aspect 30. The lighting assembly of any one of the preceding aspects, wherein the assembly comprises an elongated fiber.

Aspect 31. The lighting assembly of any one of the preceding aspects, wherein the OLED comprises an elongated fiber and the OPV device comprises an elongated fiber.

Aspect 32. A lighting assembly comprising: (a) an organic light-emitting device (OLED) fiber, the OLED fiber comprising a conductive core including a first electrode, an organic light-emitting layer surrounding the first electrode and a second electrode surrounding the organic light-emitting layer; and (b) an organic photovoltaic (OPV) fiber comprising a conductive core including a first electrode, an organic photovoltaic layer surrounding the first electrode, and a second electrode surrounding the organic photovoltaic layer, wherein the OPV fiber is electrically connected to the OLED fiber and configured to directly power the OLED fiber.

Aspect 33. The lighting assembly of aspect 32, further comprising a transparent wire case, wherein the OLED fiber and the OPV fiber are inside the transparent wire case.

Aspect 34. The lighting assembly of aspect 32, wherein the OLED fiber and OPV fiber are twisted or braided together to form a rope-like structure.

Aspect 35. The lighting assembly of aspects 32-34, wherein the second electrodes of OLED fiber and the OPV fiber are transparent.

Aspect 38. The lighting assembly of aspects 32-37, wherein the first electrode of the OLED is electrically connected to the first electrodes of the OPV fiber.

Aspect 39. The lighting assembly of aspects 32-38, wherein the second electrode of the OLED is electrically connected to the second electrode of the OPV device.

Aspect 40. The lighting assembly of aspects 32-39, wherein the first and second electrodes in the OLED fiber and in the OPV fiber comprise a cathode and an anode, and the cathode of the OLED fiber is electrically connected to the cathode of the OPV fiber and the anode of the OLED fiber is electrically connected to at least one anode the OPV fiber.

Aspect 41. The lighting assembly of aspects 32-40, further comprising a transparent barrier film surrounding at least one of the OLED fiber and OPV fiber.

Aspect 42. The lighting assembly of aspect 41, further comprising an adhesive layer disposed between the transparent barrier film and the OPV fiber or the OLED, wherein the adhesive layer is transparent.

Aspect 43. An article of clothing comprising the lighting assembly of aspects 32-42.

Aspect 44. The process of fabricating a lighting assembly, the process comprising: (a) providing a substrate; (b) providing an organic light-emitting device (OLED) comprising a bottom electrode disposed on a substrate, an organic light-emitting layer disposed on the bottom electrode and a top electrode disposed on the organic light-emitting layer; (c) depositing an insulating layer on the top electrode of the OLED; (d) providing an organic photovoltaic (OPV) device on the insulating layer, the OPV device comprising a series of cells, each cell including a bottom electrode, an organic photovoltaic layer disposed on the bottom electrode, and a top electrode disposed on the organic photovoltaic layer, wherein each cell is connected to at least one adjacent cell; and (e) connecting the OPV device to the OLED, wherein the OPV device is configured to directly power the OLED.

Aspect 45. The lighting assembly of aspect 44, wherein the providing an OLED includes using a vacuum process or a solution process to form at least one of the top electrode, bottom electrode and organic light-emitting layer.

Aspect 46. The lighting assembly of aspects 44-45 , wherein the providing an OPV includes using a vacuum process or a solution process to form at least one of the top electrode, bottom electrode and organic photovoltaic layer.

Aspect 47. The lighting assembly of any of the preceding claims, wherein the assembly has a width greater than 100 mm.

1. A lighting assembly comprising:
(a) a substrate;
(b) an organic light-emitting device (OLED) including a bottom electrode disposed on the substrate, an organic light-emitting layer disposed on the bottom electrode, and a top electrode disposed on the organic light-emitting layer;
(c) an insulating layer disposed on the top electrode of the OLED; and
(d) an organic photovoltaic (OPV) device disposed on the insulating layer, the OPV device including a series of cells, each cell comprising a bottom electrode, an organic photovoltaic layer disposed on the bottom electrode, and a top electrode disposed on the organic photovoltaic layer, wherein each cell is connected to at least one adjacent cell, and wherein the OPV device is electrically connected to the OLED and configured to directly power the OLED.

2. The lighting assembly of claim 1, wherein the top and bottom electrodes of the OPV device and the organic photovoltaic layer are disposed on the insulating layer.

3. The lighting assembly claim 1, wherein the series of cells of the OPV device are aligned in a horizontal and vertical orientation on the insulating layer defining a plurality of openings through the lighting assembly.

4. The lighting assembly of claim 1, wherein the top and bottom electrodes in the OLED and each cell in the OPV device comprise a cathode and an anode, and the cathode of the OLED is electrically connected at least one cathode of the OPV device and the anode of the OLED is electrically connected to at least one anode the OPV device.

5. The lighting assembly of claim 1, further comprising a transparent barrier film disposed on the OPV device opposite the insulating layer.

6. The lighting assembly of claim 1, further comprising an adhesive layer disposed between the transparent barrier film and the OPV device, wherein the adhesive layer is transparent.

7. The lighting assembly of claim 1, wherein the insulating layer is transparent or reflective.

8. The lighting assembly of claim 1, wherein the substrate is flexible and transparent.

9. The lighting assembly of claim 1, wherein the organic light-emitting layer is a single continuous layer disposed on the top surface of the substrate and the top surface of the bottom electrode of the OLED.

10. The lighting assembly of claim 1, wherein the top electrode of the OLED is disposed on the top surface of the organic light-emitting layer and the top surface of the substrate.

11. The lighting assembly of claim 1, wherein the assembly is a smart window or display.

12. A lighting assembly comprising:
(a) an organic light-emitting device (OLED) fiber, the OLED fiber comprising a conductive core including a first electrode, an organic light-emitting layer surrounding the first electrode and a second electrode surrounding the organic light-emitting layer; and
(b) an organic photovoltaic (OPV) fiber comprising a conductive core including a first electrode, an organic photovoltaic layer surrounding the first electrode, and a second electrode surrounding the organic photovoltaic layer, wherein the OPV fiber is electrically connected to the OLED fiber and configured to directly power the OLED fiber.

13. The lighting assembly of claim 12, further comprising a transparent wire case, wherein the OLED fiber and the OPV fiber are inside the transparent wire case.

14. The lighting assembly of claim 12, wherein the OLED fiber and OPV fiber are twisted or braided together to form a rope-like structure.

15. The lighting assembly of claim 12, wherein the second electrodes of OLED fiber and the OPV fiber are transparent.

16. The lighting assembly of claim 12, wherein the first and second electrodes in the OLED fiber and in the OPV fiber comprise a cathode and an anode, and the cathode of the OLED fiber is electrically connected to the cathode of the OPV fiber and the anode of the OLED fiber is electrically connected to at least one anode the OPV fiber.

17. An article of clothing comprising the lighting assembly of claim 12.

18. The process of fabricating a lighting assembly, the process comprising:
(a) providing a substrate;
(b) providing an organic light-emitting device (OLED) comprising a bottom electrode disposed on a substrate, an organic light-emitting layer disposed on the bottom electrode and a top electrode disposed on the organic light-emitting layer;
(c) depositing an insulating layer on the top electrode of the OLED;
(d) providing an organic photovoltaic (OPV) device on the insulating layer, the OPV device comprising a series of cells, each cell including a bottom electrode, an organic photovoltaic layer disposed on the bottom electrode, and a top electrode disposed on the organic photovoltaic layer, wherein each cell is connected to at least one adjacent cell; and
(e) connecting the OPV device to the OLED, wherein the OPV device is configured to directly power the OLED.

19. The lighting assembly of claim 18, wherein the providing an OLED includes using a vacuum process or a solution process to form at least one of the top electrode, bottom electrode and organic light-emitting layer.

20. The lighting assembly of claim 18, wherein the providing an OPV includes using a vacuum process or a solution process to form at least one of the top electrode, bottom electrode and organic photovoltaic layer
